(19) United States
(12) Patent Application Publication
(10) Pub. No.: US 2026/0134902 A1
(43) Pub. Date: May 14, 2026

(54) MEMORY BLOCK MAINTENANCE PRIORITIZATION BASED ON ACCESS FREQUENCY

(71) Applicant: Micron Technology, Inc., Boise, ID (US)

(72) Inventors: Tomer Tzvi Eliash, Sunnyvale, CA (US); Luca Porzio, Casalnuovo (IT)

(21) Appl. No.: 19/384,321

(22) Filed: Nov. 10, 2025

(30) Foreign Application Priority Data
Nov. 8, 2024 (IT) 102024000025188

(51) Int. Cl. G11C 11/406

(52) U.S. Cl. CPC G11C 11/40603; G11C 11/40615; G11C 11/40622

(57) ABSTRACT

Methods, systems, and devices for memory block maintenance prioritization based on access frequency are described. A memory system may apply a priority order for refreshes that is based on frequency of accesses at logical block addresses (LBAs) within the memory system. The memory system may perform a set of access operations to access data stored to a set of memory cells. The memory system may monitor these accesses, and then store information based on the set of access operations. The information may indicate, for each LBA of a set of LBAs of the memory system, a respective quantity of accesses associated with each LBA within a threshold duration. The memory system may perform a refresh maintenance operation including a set of refreshes of the set of memory cells. A refresh priority order for performing the set of refreshes may be based on the access frequency information.

### CROSS REFERENCE

The present application for patent claims the benefit of Italy Patent Application No. 102024000025188 by Eliash et al., entitled “MEMORY BLOCK MAINTENANCE PRIORITIZATION BASED ON ACCESS FREQUENCY,” filed Nov. 8, 2024, assigned to the assignee hereof, and expressly incorporated by reference herein.

### TECHNICAL FIELD

The following relates to one or more systems for memory, including memory block maintenance prioritization based on access frequency.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports memory block maintenance prioritization based on access frequency in accordance with examples as disclosed herein.

FIG. 2 shows an example of a flow diagram that supports memory block maintenance prioritization based on access frequency in accordance with examples as disclosed herein.

FIG. 3 shows a block diagram of a memory system that supports memory block maintenance prioritization based on access frequency in accordance with examples as disclosed herein.

FIGS. 4 and 5 show flowcharts illustrating a method or methods that support memory block maintenance prioritization based on access frequency in accordance with examples as disclosed herein.

### DETAILED DESCRIPTION

Some memory systems may experience physical stress, which may result in errors to data stored in memory cells of the memory system over time. For example, charge loss over time may cause memory cells to lose data (e.g., resulting in a ‘0’, when a ‘1’ was stored at a memory cell). Further, read disturbances (e.g., when performing reads on the memory cells) may cause the memory cells to incur data errors. Accordingly, a memory system may refresh data within memory cells periodically to reduce or otherwise mitigate the effects of physical stress and read disturbances. In some cases, the memory system may prioritize refreshes based on block family error avoidance (BFEA) bins and residual bit error rate (RBER), among other examples. Such prioritization schemes may include prioritizing (e.g., ordering, sorting) memory cells for refresh based on a threshold voltage shift associated with the memory cells, a duration since a memory cell has been programmed, an error rate associated with the memory cells, or any combination, among other examples. However, these prioritization schemes may not prioritize or otherwise account for types of data and importance of data included in the memory cells, and may not prioritize refreshing memory cells that include data important to a user (e.g., data that is frequently accessed by the user), which may result in reduced performance.

A memory system described herein may improve prioritization of refreshes for important memory cells by applying a priority order for refreshes that is based on frequency of accesses to logical block addresses (LBAs) within the memory system. The memory system may perform a set of access operations to access data stored to a set of memory cells within the memory system in response to commands from a host system, for example. The memory system may track or otherwise monitor such accesses, and then store access frequency information based on the set of access operations. The access frequency information may indicate, for each LBA of a set of LBAs of the memory system, a respective quantity of accesses associated with each LBA within a threshold duration. The memory system may perform a refresh maintenance operation including a set of refreshes of the set of memory cells within the memory system. A refresh priority order for performing the set of refreshes may be based, at least partially, on the access frequency information. In some cases, the refresh priority order may be further based on a respective BFEA bin corresponding to each LBA of the set of LBAs, a quantity of errors detected during a read of a respective memory cell, or both.

In addition to applicability in memory systems as described herein, techniques for memory block maintenance prioritization based on access frequency may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices, including automotive devices, by handling refreshes according to an access-frequency-based priority scheme, which may allow electronic devices (e.g., automotive devices) to refresh data which is more important to the user more often. For example, security-related data, safety-related data, location information, or the like may be accessed frequently within some applications, such as automotive use cases, among others, and may be of relatively high importance to a user. The proposed techniques may detect such important data based on relatively high access frequency to the data and may prioritize refreshes for the data accordingly. This may increase memory retention and accuracy of a memory device, improving performance, and thereby improving the user experience.

Features of the disclosure are illustrated and described in the context of systems, devices, and circuits. Features of the disclosure are further illustrated and described in the context of a flow diagram and flowcharts.

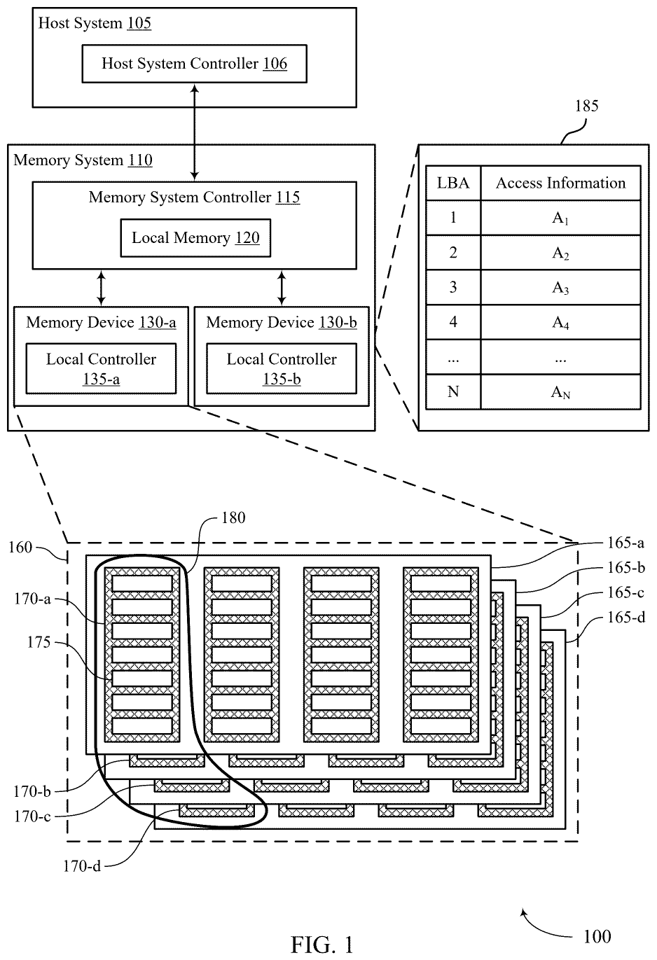

FIG. 1 shows an example of a system 100 that supports memory block maintenance prioritization based on access frequency in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some systems, due to physical stress, data that is stored in a memory device (e.g., a NAND device) may experience errors over time. Such errors may be related to charge loss over time, read disturbances, or the like. To maintain relatively high performance and to prevent data loss (e.g., due to reliability issues) a memory system may refresh the data stored in the memory device periodically. Refresh operations may be triggered by one or more algorithms. For example, the memory system may perform the refresh operations proactively (e.g., before data is lost and before a high quantity of errors is reached), reactively (due to data loss or high quantity of errors), or both. If the memory system reads a block of memory (e.g., a region of memory) and detects that an RBER of the block is above a threshold, the memory system may mark the block of memory for a refresh operation (e.g., such that the block is refreshed immediately or later on). During an idle state of the memory system, the memory system may scan a set of blocks and may determine whether a respective RBER corresponding to each block of the set of blocks is above a threshold. As described herein, an RBER may refer to a metric that indicates a quantity of errors at a region of memory (e.g., memory cells corresponding to an LBA). An RBER, or a quantity of errors, may indicate an accuracy of data received or stored at the region of memory.

Accordingly, the memory system may mark each block that is associated with respective RBER above the threshold RBER to be scheduled or otherwise prioritized for a refresh operation. In some cases, the memory system may proactively identify (e.g., search for) a block with a relatively high RBER (e.g., above the threshold) using a prioritization scheme. However, the prioritization scheme may be related to a type of block (e.g., blocks with higher bits per cell may be scanned before or more frequently than those that have fewer bits per cell). The prioritization scheme may not consider one or more other criteria (e.g., a type of data within the blocks). Some systems may not have information to indicate a type of data stored in a block (e.g., before determining a refresh priority for the block). Additionally, or alternatively, some systems may be unable to determine which blocks include data that is more important to an end-user than others.

The memory system 110 described herein may apply a priority order for refreshes that is based on frequency of accesses at LBAs within the memory system 110. The memory system 110 may perform a set of access operations to access data stored to a set of memory cells within the memory system 110 in response to commands from a host system, for example. The memory system 110 may track or otherwise monitor such accesses, and then store access frequency information based on the set of access operations. The access frequency information may indicate, for each LBA of a set of LBAs of the memory system 110, a respective quantity of accesses associated with each LBA within a threshold duration. The memory system 110 may perform a refresh maintenance operation including a set of refreshes of the set of memory cells within the memory system 110. A refresh priority order for performing the set of refreshes may be based on the access frequency information. In some cases, the refresh priority order may be further based on a respective BFEA bin corresponding to each LBA of the set of LBAs.

Techniques described herein may support storing information 185 (e.g., a table or a histogram) that includes a list of LBA identifiers (e.g., numbers) and includes access information that indicates how frequently each LBA in the list is accessed. Blocks that are accessed more frequently may be more important to a user or to a system, in some examples. Accordingly, to achieve high performance, the blocks that are accessed more frequently may have a relatively low target RBER (e.g., such blocks should maintain a relatively low RBER to reduce a risk of loss of important data for the user). Since blocks that are accessed more frequently may experience greater read disturbance relative to other blocks, such blocks may experience an increased RBER (e.g., an accelerated RBER ramp-up). Thus, the memory system 110 may maintain the information 185 such that the information 185 indicates access information (e.g., access frequency information) corresponding to each LBA of a set of LBAs within the memory system 110 and may prioritize refreshes of the memory cells based on the information 185 to ensure that important data is protected and refreshed frequently. Techniques described herein may improve memory retention of electronic devices, including automotive devices, among other devices that store relatively high priority data associated with security, safety, or the like, by identifying such data based on access frequency information and prioritizing refresh of the identified data.

As described herein, the term “block” (e.g., a block of memory) may refer to a set of memory cells associated with a single LBA or more than one LBA, in some cases. The term “scan” may refer to performing one or more detection procedures (e.g., a memory read, an error correction code (ECC) check, or both) to determine whether a block is to be refreshed. For example, the memory system 110 may scan a block of memory to determine whether the block is to be refreshed (e.g., based on one or more criteria such as BLER). The memory system 110 may use the information 185 that indicates how frequent blocks are accessed to prioritize scans of blocks that are accessed more frequently. The memory system 110 may additionally, or alternatively, use BFEA bin information associated with the blocks to further prioritize block scans that are in a particular set of bins (e.g., blocks that are in a high-priority set of bins, where a relatively low RBER is expected). The term “BFEA bin” may refer to a range of wear metrics, such as a threshold voltage shift or offset from an initial threshold voltage of a memory cell, a duration since a most recent program or refresh, or the like. For example, blocks within a single BFEA bin may be associated with similar wear metric values, and thus may be associated with a same (or similar) priority order for refreshing the blocks. As described herein, refreshing an LBA or a block may refer to refreshing memory cells that are associated with (e.g., at) the LBA.

In some implementations, the memory system 110 may scan and refresh a first set of one or more blocks that are in a first BFEA bin (e.g., a highest priority BFEA bin) before refreshing other BFEA bins. In any case, the memory system 110 may refresh blocks within a particular BFEA bin (e.g., the first BFEA bin) according to the information 185. For example, within a given BFEA bin, the memory system 110 may perform refreshes in an order that prioritizes blocks with relatively higher access frequencies over blocks with lower access frequencies. After refreshing the first set of one or more blocks, the memory system 110 may move the first set of one or more blocks to one or more lower BFEA bins (e.g., having a relatively lower priority for refresh). Then, the memory system 110 may scan a second set of one or more blocks within the first BFEA that are accessed less frequently than the first set of one or more blocks. The memory system 110 may refresh the second set of one or more blocks (e.g., based on an RBER of the second set), and so on. In some implementations, the memory system 110 may perform a last scan (e.g., with a lowest priority) on a third set of one or more blocks that includes data that is accessed relatively infrequently (e.g., cold data may be last to scan). However, in some examples, data that is accessed relatively infrequently may be marked in a relatively high-priority BFEA bin. In such examples, the memory system 110 may refresh the data (in accordance with the elevated block priority) despite that the data is accessed relatively infrequently (e.g., to avoid reliability risks).

In some implementations, the memory system 110 may store and maintain the information 185 as a table that indicates pairs of information. Each pair may include an LBA identifier (e.g., an LBA number) and a quantity of accesses within a duration, Aₓ (e.g., a predefined period). The memory system 110 may correlate the table with BFEA bin information to create sub-priorities within the BFEA bins. For example, the memory system 110 may scan blocks (and subsequently refresh the blocks) in relatively high-priority BFEA bins first. Then, the memory system 110 may scan blocks within each other BFEA bin in a descending-priority order, according to BFEA bin. For BFEA bins that are in a relatively low-risk area (e.g., middle- to low-priority BFEA bins), the memory system 110 may prioritize scanning blocks that are associated with more frequent accesses (e.g., based on the information 185). For instance, within each BFEA bin, the memory system 110 may scan blocks (and may subsequently refresh the blocks) according to the information 185. For example, the memory system 110 may refresh a first block within a first BFEA bin before a second block within the first BFEA bin if the first block is associated with more frequent accesses according to the information 185. In some cases, the memory system 110 may scan blocks in relatively high BFEA bins before the memory system 110 scans blocks that are accessed more frequently (e.g., to maintain data integrity).

In some examples, the memory system 110 may retain the information 185 corresponding to one or more blocks (e.g., even after refreshing the one or more blocks). Accordingly, the memory system 110 may monitor accesses using logical addresses (e.g., rather than physical addresses). Based on monitoring the accesses using logical addresses, the memory system 110 may generate and store the information 185 such that the information 185 may be retainable (and applicable to the logical addresses) after refreshing.

The memory system 110 may store the information 185 in a table format, in some examples. Table 1 illustrates an example format for storage of the information 185. In some cases, the memory system 110 may store the information 185 according to one or more other schemes or formats, such as a histogram, a set of arrays, a set of vectors, or the like. In any case, the memory system 110 may prioritize refreshes of blocks (corresponding to LBAs) according to the information 185 (represented by table 1), BFEA bin information, or both. Table 2 represents an example set of BFEA bin organization information.

Table 1 includes a first column representing a list of LBA identifiers (or numbers) and a second column representing a quantity of accesses during a threshold duration for each LBA identifier. The threshold duration may be a time measurement such as minutes, seconds, hours, days, weeks, or the like (e.g., the last 24 hours). In some cases, the threshold duration may be based on a configuration of the memory system 110 (e.g., as received from a host system) or may be based on a one or more procedures of the memory system 110 (e.g., a boot-up procedure). Table 2 includes a first column representing a list of BFEA bins (e.g., ranges of wear metrics) and a second column representing LBA identifiers (or numbers). That is, Table 2 may represent an association of LBA identifiers and BFEA bins (e.g., showing which LBAs are within each BFEA bin).

TABLE 1
Access Frequency Tracking Information

| | Quantity of Accesses within |
|---|---|
| LBA number | Threshold Duration |
| 1 | 2 |
| 2 | 1 |
| 3 | 15 |
| 4 | 4 |
| 5 | 7 |
| 6 | 25 |
| 7 | 0 |
| 8 | 0 |
| 9 | 1 |
| 10 | 50 |
| 11 | 31 |
| 12 | 11 |
| 13 | 25 |
| 14 | 0 |
| 15 | 0 |
| 16 | 1 |

TABLE 2
BFEA Bin Tracking Information

| BFEA Bin | LBA number |
|---|---|
| 0 | 4, 5, 16 |
| 1 | 3 |
| 2 | |
| 3 | 14 |
| 4 | 12, 15 |
| 5 | 11 |
| 6 | |
| 7 | 1, 6, 16 |
| 8 | 2, 13 |
| 9 | 8 |
| 10 | 9, 10 |
| 11 | |
| 12 | |
| 13 | |
| 14 | 7 |
| 15 | |

In accordance with the information in Table 1 and Table 2 (e.g., the information 185 and the BFEA bin information), the memory system 110 may determine a priority order for scanning and refreshing blocks of memory (e.g., memory cells associated with LBAs). The priority order may be determined based on one or more aspects in accordance with the information 185 and the BFEA bin information. The memory system 110 may be configured to operate according to one or more prioritization schemes from among a set of candidate prioritization schemes, each associated with a different technique or process for generating the priority order for refreshes.

In a first example prioritization scheme, the priority order may be based (solely) on access frequency. That is, the memory system 110 may refresh blocks in an order from blocks accessed at a highest frequency to blocks accessed at a lowest frequency. For example, with reference to the example illustrated in Table 1 and Table 2, the memory system 110 may prioritize refreshing LBA 10, then LBA 11. Since LBA 6 and LBA 13 are associated with equally frequent accesses according to Table 1, LBA 6 and LBA 13 may have an equal priority according to the first prioritization scheme. Thus, the memory system 110 may prioritize refreshing LBAs according to the information 185 (e.g., Table 1) in an order from highest frequency to lowest frequency. In some implementations, the memory system 110 may prioritize blocks that have higher frequency of accesses over blocks that are in higher BFEA bins (e.g., for middle-priority BFEA bins). For example, the memory system 110 may prioritize LBA 11, LBA 13, and LBA 6 over LBA 9 since these LBAs are associated with more frequent accesses than LBA 9 (by a relatively high amount), despite that LBA 9 is in a higher BFEA bin.

In a second example prioritization scheme, the priority order may be based on BFEA bins. As a sub-priority within each BFEA bin, the priority order may be based on access frequency. For example, with reference to the example information illustrated in Table 1 and Table 2, the memory system 110 may prioritize scanning and refreshing LBAs within BFEA bin 14 (e.g., LBA 7), and then LBAs within BFEA bin 10 (e.g., LBA 9 and LBA 10). In accordance with the sub-priority, the memory system 110 may prioritize refreshing LBA 10 over LBA 9, since LBA 10 is associated with more frequent accesses than LBA 9 according to the information 185 (e.g., since 50 is greater than 1). In some cases, the memory system 110 may scan and refresh LBA 9 before LBA 3 (e.g., since LBA 3 is in a much lower BFEA bin than LBA 9). Thus, the memory system 110 may determine a priority order for scanning and refreshing a set of blocks based on one or more thresholds associated with a difference between BFEA bins, a difference between access frequency measurement, or both. The one or more thresholds may be based on a configuration of the memory system 110 (e.g., based on one or more tuning or testing mechanisms).

In a third example prioritization scheme, the priority order may be based on a threshold quantity of BFEA bins and, after the threshold quantity of BFEA bins is refreshed, the priority order may prioritize refreshing blocks based on access frequency (e.g., as in the first prioritization scheme). For example, with reference to the example information illustrated in Table 1 and Table 2, the memory system 110 may determine to scan LBA 7 first (e.g., according to a first priority), since LBA 7 is in a relatively high BFEA bin (e.g., due to reliability risk). After all LBA(s) in at least the top threshold quantity of BFEA bins are refreshed, the memory system 110 may prioritize subsequent refreshes based on access frequency. For example, if the threshold is three, the memory system may refresh LBA 7, which may be the only LBA in the top three BFEA bins. As such, the memory system 110 may subsequently prioritize scanning and refreshing LBA 10 over LBA 9, since LBA 10 is associated with more frequent accesses than LBA 9 according to the information 185 (e.g., since 50 is greater than 1). In another example, the memory system 110 may determine that the threshold quantity of BFEA bins includes BFEA bins 14, 10, and 9. Accordingly, the memory system 110 may prioritize refreshing LBAs within BFEA bins 14, 10 and 9 (e.g., LBAs 7, 10, 9, and 8, in that order). After refreshing LBAs within the threshold quantity of BFEA bins, the memory system 110 may prioritize refreshing LBAs based on access frequency (e.g., according to the first example prioritization scheme).

In a fourth example prioritization scheme, the memory system 110 may prioritize refreshing one or more blocks that have a quantity of errors above a threshold, and then may prioritize blocks based on the first, second, or third prioritization scheme, as described herein. For example, with reference to the example information illustrated in Table 1 and Table 2, the memory system 110 may detect that LBA 11 has a quantity of errors that is above a threshold quantity of errors (e.g., having an RBER above a threshold). In response, the memory system 110 may prioritize refreshing the memory cell corresponding to LBA 11 before other LBAs that have relatively less errors. After refreshing LBA 11 (and other LBAs with errors exceeding the threshold quantity of errors), the memory system 110 may prioritize refreshing LBAs according to access frequency, according to BFEA bin, according to a threshold quantity of BFEA bins, or a combination thereof (e.g., according to the other prioritization schemes as described herein).

In some implementations, the memory system 110 may perform refreshes on memory cells within one or more blocks (e.g., associated with one or more LBAs) according to a refresh priority order that is based on access information associated with the one or more blocks (e.g., based on frequency of accesses in each block, based on an access pattern detected at each block, or based on other similar information as described herein). In some cases, the memory system 110 may prioritize refreshing blocks that are accessed more frequently over blocks that have a relatively high voltage shift (e.g., if the blocks that have a relatively high voltage shift are accessed relatively infrequently). That is, the memory system 110 may prioritize block refreshes to improve an average performance of memory cells (e.g., prioritizing long-term performance despite having momentary degradation in some memory cells). Thus, the memory system 110 may handle block refreshes in a timely manner such that data within the blocks is not lost.

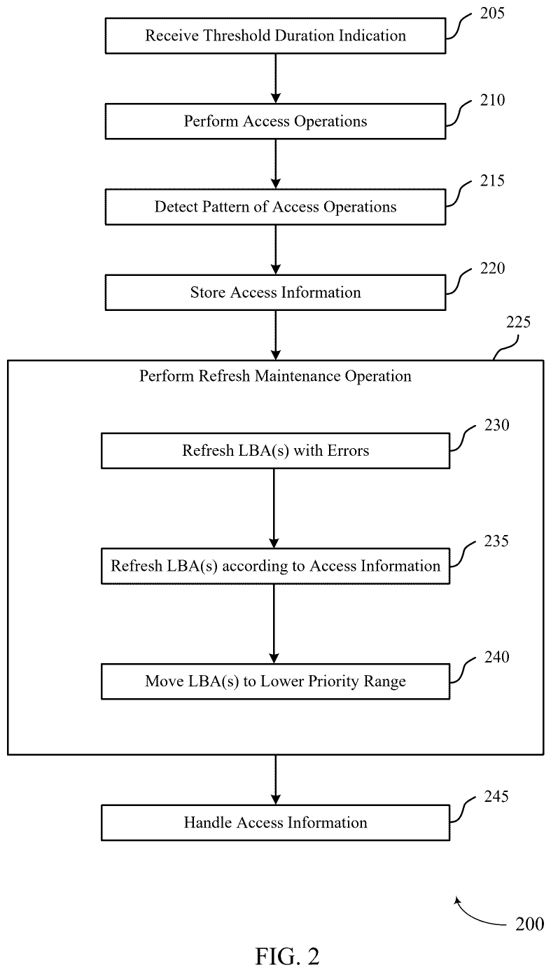

FIG. 2 shows an example of a flow diagram 200 that supports memory block maintenance prioritization based on access frequency in accordance with examples as disclosed herein. One or more entities may perform the operations of the flow diagram 200. For example, the one or more entities may include a memory system 110, a host system 105, or both, which may be examples of the corresponding devices as described with respect to FIG. 1. In the following description of the flow diagram 200, the described operations may be performed in a different order than the example order shown. Some operations may also be omitted from the flow diagram 200, and other operations may be added to the flow diagram 200. Further, although some operations or signaling may be shown to occur at different times for discussion purposes, these operations may actually occur at the same time. The processes described in the flow diagram 200 may improve memory retention of electronic devices, including automotive devices, among other devices that store relatively high priority data associated with security, safety, or the like, by identifying such data based on access frequency information and prioritizing refresh of the identified data.

At 205, the memory system 110 may receive an indication of a threshold duration. For example, the memory system 110 may receive the indication of the threshold duration from a user (e.g., via a user interface), from a host system (e.g., via a configuration message), or a combination thereof.

At 210, the memory system 110 may perform a set of access operations to access data stored to a set of memory cells within the memory system 110. The access operations may include read operations, write operations, erase operations, move operations, other access operations, or any combination thereof based on one or more access commands received from a host system. At 215, in some examples, the memory system 110 may detect a pattern of access operations. For example, if the memory system is operating in a certain mode or performing a certain operation, such as a boot-up operation, the memory system 110 may monitor for patterns in access operations. That is, the memory system 110 may determine that a same or similar pattern of accesses is performed each time the memory system 110 boots up. The memory system 110 may store information that indicates the identified pattern.

At 220, the memory system 110 may store information based on the set of access operations. The information may indicate, for each LBA of a set of LBAs of the memory system 110, a respective quantity of accesses associated with (e.g., performed at) each LBA within a threshold duration. Accordingly, the information may be based on the indication of the threshold duration (e.g., received at 205). The information may represent an example of the information 185 described with reference to FIG. 1. In some examples, the information may be further based on the pattern of access operations (e.g., detected at 215). For example, the information may indicate an expected or predicted pattern of access frequency for one or more LBAs over a predicted duration.

The information may map each LBA of the set of LBAs to a respective count that indicates the respective quantity of accesses associated with each LBA within the threshold duration. In some cases, the memory system 110 may store the information in non-volatile memory within the memory system 110 for a threshold duration. Additionally, or alternatively, the memory system 110 may store the information in volatile memory (e.g., for a same or a different threshold duration).

At 225, the memory system 110 may perform a refresh maintenance operation including a set of refreshes of the set of memory cells within the memory system 110. The memory system 110 may perform the refresh maintenance operation during an idle mode of the memory system 110, in some examples. The memory system 110 may perform the set of refreshes in a refresh priority order that is based on the information (e.g., associated with the set of access operations). The memory system 110 may determine a refresh priority order in which to refresh the set of LBAs based on one or more rules associated with the refresh priority order. In some implementations, the refresh maintenance operation may refer to a set of refresh operations performed during a duration. In some examples, the memory system 110 may perform one or more refresh maintenance operations (e.g., in cycles of refreshes) over time to ensure that data is not lost during operation of the memory system 110.

In some examples, the prioritization order may be associated with prioritization, by the memory system 110, of refreshes for one or more memory cells that are associated with a quantity of errors above a threshold quantity. For example, at 230, in some examples, the memory system 110 may refresh one or more first LBAs of the memory system that are associated with respective quantities of errors that satisfy a threshold error quantity. That is, the memory system 110 may detect that the one or more LBAs each have an error quantity that satisfies a threshold error quantity. The memory system 110 may detect the one or more LBAs during the access operations performed at 210. For example, the memory system 110 may perform one or more reads that detect or otherwise identify the errors. In such cases, the refresh priority order may include a first priority for performing refreshes on the one or more LBAs that are associated with the respective quantities of errors that satisfy the threshold error quantity, and a second priority, lower than the first priority, that is based on the information. For example, the memory system 110 may refresh the one or more LBAs that each have an error quantity satisfying the threshold error quantity before refreshing one or more other LBAs (e.g., which are accessed either frequently or infrequently, according to the information).

At 235, the memory system 110 may refresh a first memory cell associated with a first LBA in accordance with the refresh priority order. The memory system 110 may refresh the first memory cell after refreshing the one or more memory cells associated with the threshold quantity of errors, in some examples (e.g., if the prioritization order prioritizes the error threshold). Additionally, or alternatively, the memory system 110 may skip refreshing the one or more memory cells and may start the refresh maintenance operation by refreshing the first memory cell in accordance with the first memory cell having a higher priority in the refresh priority order than other memory cells.

In some examples, the memory system 110 may refresh the first memory cell associated with the first LBA before refreshing a second memory cell associated with a second LBA if the information indicates that the first LBA is accessed more frequently than the second LBA within the threshold duration. That is, the refresh priority order may prioritize LBAs with greater access frequencies over LBAs with lower access frequencies.

Additionally, or alternatively, the refresh priority order may be based on a respective range of a set of ranges of wear metrics associated with the memory system 110. Each respective range may be associated with one or more LBAs of the set of LBAs. The set of ranges may include BFEA bins as described herein. In some cases, the set of ranges of wear metrics may include a set of ranges of threshold voltage shifts associated with each memory cell of the set of memory cells, a set of ranges of time periods since a most recent refresh of each memory cell of the set of memory cells, or a combination thereof. In such examples, the memory system 110 may perform, during the idle mode of the memory system 110, the first refresh of a memory cell based on an LBA of the memory cell being associated with one or more wear metrics above a wear metric threshold. In some cases, the one or more wear metrics may include a duration since a most recent refresh of the memory cell, a shift in a threshold voltage of the memory cell, or both.

In some implementations, the refresh priority order may be based on some combination of BFEA bin prioritization and access frequency prioritization. For example, the memory system 110 may perform, in accordance with a first priority in the refresh priority order, one or more first refreshes of a first subset of memory cells that is included within a first range of the set of ranges of wear metrics (e.g., a first BFEA bin). The first subset of memory cells may be associated with the first priority in the refresh priority order based on the first subset of memory cells being included within the first range, and based on the first range having a higher priority than other ranges within the set of ranges of wear metrics. That is, the memory system 110 may refresh LBAs in higher priority ranges before refreshing LBAs within lower priority ranges. The memory system 110 may perform the one or more first refreshes in accordance with a refresh sub-priority order that is based on the information (e.g., that is based on access frequency or access pattern). Thus, in some cases, the memory system 110 may refresh LBAs within a single range according to access frequency (e.g., refreshing LBAs with higher access frequency first). Additionally, or alternatively, the memory system 110 may refresh LBAs that are accessed more frequently before LBAs that are in a higher-priority range.

After performing the one or more first refreshes, and in accordance with a second priority in the refresh priority order, the memory system 110 may perform one or more second refreshes of a second subset of memory cells that is included within a second range of the set of ranges of wear metrics (e.g., a second BFEA bin). The second subset of memory cells may be associated with the second priority in the refresh priority order based on the second subset of memory cells being included within the second range, and based on the second range having a lower priority than the first range and a higher priority than one or more other ranges of the set of ranges of wear metrics. The memory system 110 may perform the one or more second refreshes in accordance with the refresh sub-priority order that is based on the information (e.g., based on access frequency or access pattern).

In some other examples, the refresh prioritization order may prioritize refreshes of some threshold quantity of ranges of wear metrics before prioritizing remaining LBAs according to access frequency. For example, the memory system 110 may perform, in accordance with a first priority in the refresh priority order, one or more first refreshes of a first subset of memory cells associated with a first subset of LBAs. The first subset of LBAs may be associated with the first priority based on the first subset of LBAs being included within a threshold set of one or more first ranges of the set of ranges of wear metrics. After performing the one or more first refreshes, and in accordance with a second priority in the refresh priority order, the memory system 110 may perform one or more second refreshes of a second subset of memory cells based on the information indicating that LBAs of the second subset of memory cells are associated with more frequent accesses, within the threshold duration, than one or more other LBAs of the set of LBAs. In some examples as described herein, the set of ranges of wear metrics may include a set of BFEA bins.

At 240, in some implementations, the memory system 110 may move LBAs that have been refreshed during the refresh maintenance operation to ranges of wear metrics associated with lower priorities. For example, the memory system 110 may perform one or more first refreshes of one or more memory cells associated with a first subset of LBAs within a first range of the set of ranges of wear metrics. Then, at 240, the memory system may move the first subset of LBAs to a second range of the set of ranges of wear metrics in response to the one or more first refreshes. The second range may be associated with a lower priority in the refresh priority order than the first range.

At 245, the memory system 110 may handle the information according to one or more aspects (e.g., after using it to perform the refresh maintenance operation). For example, the memory system 110 may retain, in the memory system 110, the information for the set of LBAs after performing the set of refreshes of the set of memory cells associated with the set of LBAs (e.g., to use for later refresh decisions). Additionally, or alternatively, the memory system 110 may reset, in response to performing the set of refreshes of the set of memory cells, the information for one or more LBAs associated with the set of memory cells.

The memory system 110 may thereby track and store information associated with frequencies at which memory cells are accessed within the memory system 110 and use the access frequency information to prioritize and order refreshes that are performed during an idle mode and a corresponding refresh maintenance operation. Prioritizing the refreshes based in part on the access frequency information may support prioritization of refreshes for memory cells that store relatively important data for a user application over other memory cells that may be associated with greater wear metrics but may not be used as frequency or may not store as important of data, which may maintain more reliable and secure data for the user application, thereby improving performance.

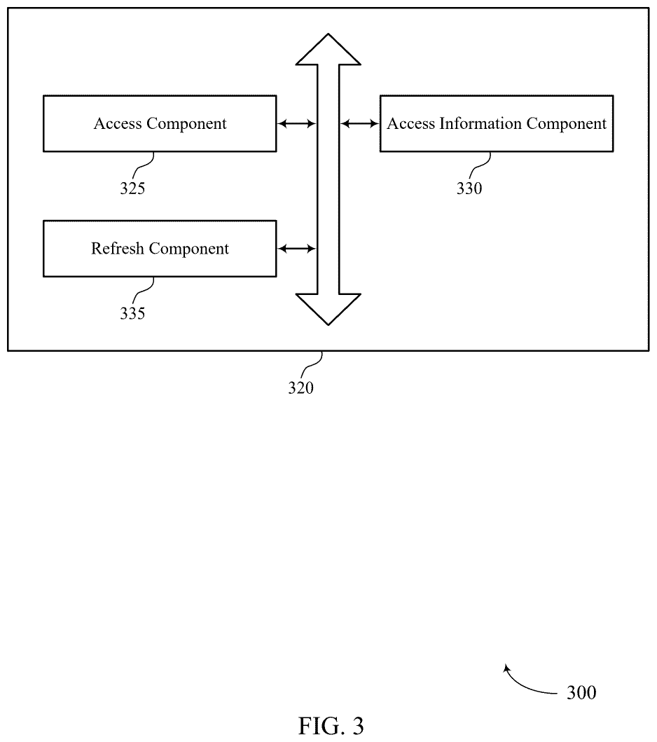

FIG. 3 shows a block diagram 300 of a memory system 320 that supports memory block maintenance prioritization based on access frequency in accordance with examples as disclosed herein. The memory system 320 may be an example of aspects of a memory system as described with reference to FIGS. 1 through 2. The memory system 320, or various components thereof, may be an example of means for performing various aspects of memory block maintenance prioritization based on access frequency as described herein. For example, the memory system 320 may include an access component 325, an access information component 330, a refresh component 335, or any combination thereof. Each of these components, or components of subcomponents thereof (e.g., one or more processors, one or more memories), may communicate, directly or indirectly, with one another (e.g., via one or more buses).

The access component 325 may be configured as or otherwise support a means for performing a plurality of access operations to access data stored to a plurality of memory cells within the memory system. The access information component 330 may be configured as or otherwise support a means for storing, based at least in part on the plurality of access operations, information that indicates, for each LBA of a plurality of LBAs of the memory system, a respective quantity of accesses associated with each LBA within a threshold duration. The refresh component 335 may be configured as or otherwise support a means for performing a refresh maintenance operation including a plurality of refreshes of the plurality of memory cells within the memory system, where the plurality of refreshes are performed in a refresh priority order that is based at least in part on the information.

In some examples, to support performing the refresh maintenance operation, the refresh component 335 may be configured as or otherwise support a means for refreshing, in accordance with the refresh priority order, a first memory cell associated with a first LBA before refreshing a second memory cell associated with a second LBA based at least in part on the information indicating that the first LBA is accessed more frequently than the second LBA within the threshold duration, where the refresh priority order prioritizes LBAs with greater access frequencies over LBAs with lower access frequencies.

In some examples, to support storing the information, the access information component 330 may be configured as or otherwise support a means for storing the information within the memory system, where the information maps each LBA of the plurality of LBAs to a respective count that indicates the respective quantity of accesses associated with each LBA within the threshold duration.

In some examples, the information is stored in non-volatile memory within the memory system for the threshold duration.

In some examples, the information is stored in volatile memory.

In some examples, the refresh priority order is further based at least in part on a respective range, of a plurality of ranges of wear metrics associated with the memory system, that is associated with each LBA of the plurality of LBAs. In some examples, the plurality of ranges of wear metrics includes a plurality of ranges of threshold voltage shifts associated with each memory cell of the plurality of memory cells, a plurality of ranges of time periods since a most recent refresh of each memory cell of the plurality of memory cells, or any combination thereof.

In some examples, to support performing the refresh maintenance operation, the refresh component 335 may be configured as or otherwise support a means for performing, in accordance with a first priority in the refresh priority order, one or more first refreshes of a first subset of memory cells that is included within a first range of the plurality of ranges of wear metrics, where the first subset of memory cells is associated with the first priority in the refresh priority order based at least in part on the first subset of memory cells being included within the first range having a higher priority than other ranges within the plurality of ranges of wear metrics, and where the one or more first refreshes are performed in accordance with a refresh sub-priority order that is based at least in part on the information. In some examples, to support performing the refresh maintenance operation, the refresh component 335 may be configured as or otherwise support a means for performing, after performing the one or more first refreshes and in accordance with a second priority in the refresh priority order, one or more second refreshes of a second subset of memory cells that is included within a second range of the plurality of ranges of wear metrics, where the second subset of memory cells is associated with the second priority in the refresh priority order based at least in part on the second subset of memory cells being included within the second range having a lower priority than the first range and a higher priority than one or more other ranges of the plurality of ranges of wear metrics, and where the one or more second refreshes are performed in accordance with the refresh sub-priority order that is based at least in part on the information.

In some examples, to support performing the refresh maintenance operation, the refresh component 335 may be configured as or otherwise support a means for performing, in accordance with a first priority in the refresh priority order, one or more first refreshes of a first subset of memory cells associated with a first subset of LBAs, where the first subset of LBAs is associated with the first priority based at least in part on the first subset of LBAs being included within a threshold set of one or more first ranges, of the plurality of ranges of wear metrics. In some examples, to support performing the refresh maintenance operation, the refresh component 335 may be configured as or otherwise support a means for performing, after performing the one or more first refreshes and in accordance with a second priority in the refresh priority order, one or more second refreshes of a second subset of memory cells based at least in part on the information indicating that LBAs of the second subset of memory cells are associated with more frequent accesses, within the threshold duration, than one or more other LBAs of the plurality of LBAs.

In some examples, to support performing the refresh maintenance operation, the refresh component 335 may be configured as or otherwise support a means for performing one or more first refreshes of one or more memory cells associated with a first subset of LBAs within a first range of the plurality of ranges of wear metrics. In some examples, to support performing the refresh maintenance operation, the refresh component 335 may be configured as or otherwise support a means for moving, based at least in part on the one or more first refreshes, the first subset of LBAs to a second range of the plurality of ranges of wear metrics, the second range associated with a lower priority in the refresh priority order than the first range.

In some examples, the plurality of ranges of wear metrics includes a plurality of BFEA bins.

In some examples, the refresh component 335 may be configured as or otherwise support a means for detecting, in accordance with one or more read operations included in the plurality of access operations, one or more LBAs of the memory system that are associated with respective quantities of errors that satisfy a threshold error quantity, where the refresh priority order includes a first priority for performing refreshes on the one or more LBAs that are associated with the respective quantities of errors that satisfy the threshold error quantity, and a second priority, lower than the first priority, that is based at least in part on the information.

In some examples, the access information component 330 may be configured as or otherwise support a means for receiving an indication of the threshold duration, where the information is based at least in part on the indication of the threshold duration.

In some examples, the access information component 330 may be configured as or otherwise support a means for retaining, in the memory system, the information for the plurality of LBAs after performing the plurality of refreshes of the plurality of memory cells associated with the plurality of LBAs.

In some examples, the access information component 330 may be configured as or otherwise support a means for resetting, in response to performing the plurality of refreshes of the plurality of memory cells, the information for one or more LBAs associated with the plurality of memory cells.

In some examples, the access information component 330 may be configured as or otherwise support a means for detecting a pattern of access operations performed during a boot-up operation of the memory system, where the information is further based at least in part on the pattern of access operations.

In some examples, the access component 325 may be configured as or otherwise support a means for performing a plurality of access operations to access data stored to a plurality of memory cells within the memory system. In some examples, the access information component 330 may be configured as or otherwise support a means for storing, based at least in part on the plurality of access operations, information that indicates, for each LBA of a plurality of LBAs of the memory system, a respective quantity of accesses associated with each LBA within a threshold duration. In some examples, the refresh component 335 may be configured as or otherwise support a means for performing, during an idle mode of the memory system, a first refresh of a first memory cell based at least in part on the information indicating that a first LBA of the first memory cell is associated with a first quantity of accesses within the threshold duration that is greater than other quantities of accesses associated with other LBAs of the plurality of LBAs. In some examples, the refresh component 335 may be configured as or otherwise support a means for performing, during the idle mode of the memory system and after the first refresh, a second refresh of a second memory cell based at least in part on the information indicating that a second LBA of the second memory cell is associated with a second quantity of accesses within the threshold duration that is less than the first quantity of accesses.

In some examples, the refresh component 335 may be configured as or otherwise support a means for performing a refresh maintenance operation during the idle mode of the memory system, where the refresh maintenance operation includes the first refresh and the second refresh.

In some examples, the refresh component 335 may be configured as or otherwise support a means for performing, during the idle mode of the memory system and before the first refresh, a third refresh of a third memory cell based at least in part on a third LBA of the third memory cell having a quantity of errors that is above a threshold quantity of errors.

In some examples, the refresh component 335 may be configured as or otherwise support a means for performing, during the idle mode of the memory system and before the first refresh, a third refresh of a third memory cell based at least in part on a third LBA of the third memory cell being associated with one or more wear metrics above a wear metric threshold.

In some examples, the one or more wear metrics include a duration since a most recent refresh of the third memory cell, a shift in a threshold voltage of the third memory cell, or both.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

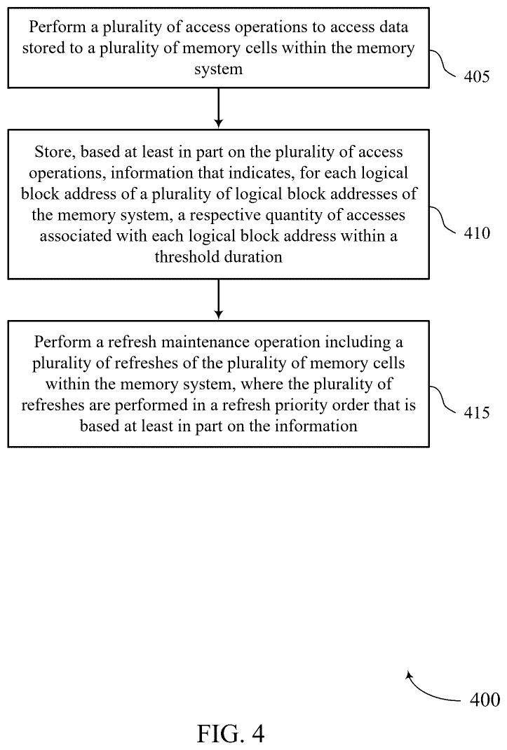

FIG. 4 shows a flowchart illustrating a method 400 that supports memory block maintenance prioritization based on access frequency in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the method may include performing a plurality of access operations to access data stored to a plurality of memory cells within the memory system. In some examples, aspects of the operations of 405 may be performed by an access component 325 as described with reference to FIG. 3.

At 410, the method may include storing, based at least in part on the plurality of access operations, information that indicates, for each LBA of a plurality of LBAs of the memory system, a respective quantity of accesses associated with each LBA within a threshold duration. In some examples, aspects of the operations of 410 may be performed by an access information component 330 as described with reference to FIG. 3.

At 415, the method may include performing a refresh maintenance operation including a plurality of refreshes of the plurality of memory cells within the memory system, where the plurality of refreshes are performed in a refresh priority order that is based at least in part on the information. In some examples, aspects of the operations of 415 may be performed by a refresh component 335 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for performing a plurality of access operations to access data stored to a plurality of memory cells within the memory system; storing, based at least in part on the plurality of access operations, information that indicates, for each LBA of a plurality of LBAs of the memory system, a respective quantity of accesses associated with each LBA within a threshold duration; and performing a refresh maintenance operation including a plurality of refreshes of the plurality of memory cells within the memory system, where the plurality of refreshes are performed in a refresh priority order that is based at least in part on the information.

Aspect 2: The method, apparatus, or non-transitory computer-readable medium of aspect 1, where performing the refresh maintenance operation includes operations, features, circuitry, logic, means, or instructions, or any combination thereof for refreshing, in accordance with the refresh priority order, a first memory cell associated with a first LBA before refreshing a second memory cell associated with a second LBA based at least in part on the information indicating that the first LBA is accessed more frequently than the second LBA within the threshold duration, where the refresh priority order prioritizes LBAs with greater access frequencies over LBAs with lower access frequencies.

Aspect 3: The method, apparatus, or non-transitory computer-readable medium of any of aspects 1 through 2, where storing the information includes operations, features, circuitry, logic, means, or instructions, or any combination thereof for storing the information within the memory system, where the information maps each LBA of the plurality of LBAs to a respective count that indicates the respective quantity of accesses associated with each LBA within the threshold duration.

Aspect 4: The method, apparatus, or non-transitory computer-readable medium of aspect 3, where the information is stored in non-volatile memory within the memory system for the threshold duration.

Aspect 5: The method, apparatus, or non-transitory computer-readable medium of any of aspects 3 through 4, where the information is stored in volatile memory.

Aspect 6: The method, apparatus, or non-transitory computer-readable medium of any of aspects 1 through 5, where the refresh priority order is further based at least in part on a respective range, of a plurality of ranges of wear metrics associated with the memory system, that is associated with each LBA of the plurality of LBAs and the plurality of ranges of wear metrics includes a plurality of ranges of threshold voltage shifts associated with each memory cell of the plurality of memory cells, a plurality of ranges of time periods since a most recent refresh of each memory cell of the plurality of memory cells, or any combination thereof.

Aspect 7: The method, apparatus, or non-transitory computer-readable medium of aspect 6, where performing the refresh maintenance operation includes operations, features, circuitry, logic, means, or instructions, or any combination thereof for performing, in accordance with a first priority in the refresh priority order, one or more first refreshes of a first subset of memory cells that is included within a first range of the plurality of ranges of wear metrics, where the first subset of memory cells is associated with the first priority in the refresh priority order based at least in part on the first subset of memory cells being included within the first range having a higher priority than other ranges within the plurality of ranges of wear metrics, and where the one or more first refreshes are performed in accordance with a refresh sub-priority order that is based at least in part on the information and performing, after performing the one or more first refreshes and in accordance with a second priority in the refresh priority order, one or more second refreshes of a second subset of memory cells that is included within a second range of the plurality of ranges of wear metrics, where the second subset of memory cells is associated with the second priority in the refresh priority order based at least in part on the second subset of memory cells being included within the second range having a lower priority than the first range and a higher priority than one or more other ranges of the plurality of ranges of wear metrics, and where the one or more second refreshes are performed in accordance with the refresh sub-priority order that is based at least in part on the information.

Aspect 8: The method, apparatus, or non-transitory computer-readable medium of any of aspects 6 through 7, where performing the refresh maintenance operation includes operations, features, circuitry, logic, means, or instructions, or any combination thereof for performing, in accordance with a first priority in the refresh priority order, one or more first refreshes of a first subset of memory cells associated with a first subset of LBAs, where the first subset of LBAs is associated with the first priority based at least in part on the first subset of LBAs being included within a threshold set of one or more first ranges, of the plurality of ranges of wear metrics and performing, after performing the one or more first refreshes and in accordance with a second priority in the refresh priority order, one or more second refreshes of a second subset of memory cells based at least in part on the information indicating that LBAs of the second subset of memory cells are associated with more frequent accesses, within the threshold duration, than one or more other LBAs of the plurality of LBAs.

Aspect 9: The method, apparatus, or non-transitory computer-readable medium of any of aspects 6 through 8, where performing the refresh maintenance operation includes operations, features, circuitry, logic, means, or instructions, or any combination thereof for performing one or more first refreshes of one or more memory cells associated with a first subset of LBAs within a first range of the plurality of ranges of wear metrics and moving, based at least in part on the one or more first refreshes, the first subset of LBAs to a second range of the plurality of ranges of wear metrics, the second range associated with a lower priority in the refresh priority order than the first range.

Aspect 10: The method, apparatus, or non-transitory computer-readable medium of any of aspects 6 through 9, where the plurality of ranges of wear metrics includes a plurality of block family error avoidance (BFEA) bins.

Aspect 11: The method, apparatus, or non-transitory computer-readable medium of any of aspects 1 through 10, further including operations, features, circuitry, logic, means, or instructions, or any combination thereof for detecting, in accordance with one or more read operations included in the plurality of access operations, one or more LBAs of the memory system that are associated with respective quantities of errors that satisfy a threshold error quantity, where the refresh priority order includes a first priority for performing refreshes on the one or more LBAs that are associated with the respective quantities of errors that satisfy the threshold error quantity, and a second priority, lower than the first priority, that is based at least in part on the information.

Aspect 12: The method, apparatus, or non-transitory computer-readable medium of any of aspects 1 through 11, further including operations, features, circuitry, logic, means, or instructions, or any combination thereof for receiving an indication of the threshold duration, where the information is based at least in part on the indication of the threshold duration.

Aspect 13: The method, apparatus, or non-transitory computer-readable medium of any of aspects 1 through 12, further including operations, features, circuitry, logic, means, or instructions, or any combination thereof for retaining, in the memory system, the information for the plurality of LBAs after performing the plurality of refreshes of the plurality of memory cells associated with the plurality of LBAs.

Aspect 14: The method, apparatus, or non-transitory computer-readable medium of any of aspects 1 through 13, further including operations, features, circuitry, logic, means, or instructions, or any combination thereof for resetting, in response to performing the plurality of refreshes of the plurality of memory cells, the information for one or more LBAs associated with the plurality of memory cells.

Aspect 15: The method, apparatus, or non-transitory computer-readable medium of any of aspects 1 through 14, further including operations, features, circuitry, logic, means, or instructions, or any combination thereof for detecting a pattern of access operations performed during a boot-up operation of the memory system, where the information is further based at least in part on the pattern of access operations.

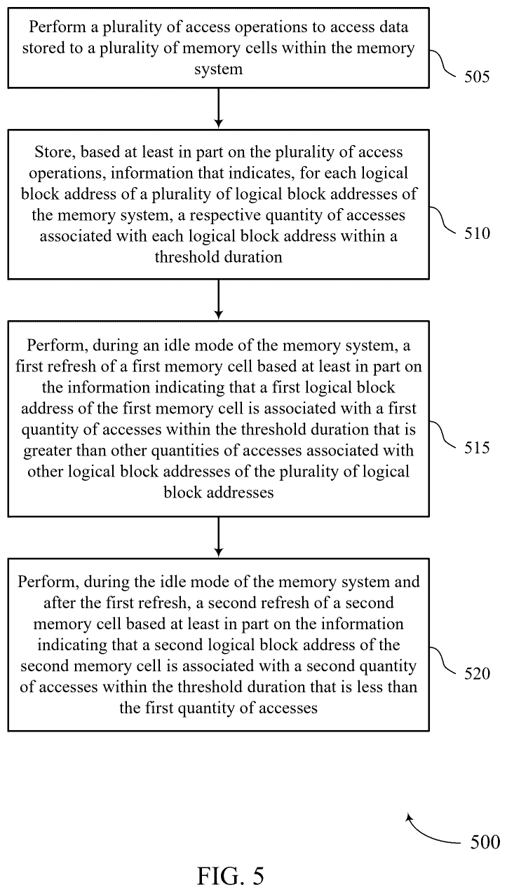

FIG. 5 shows a flowchart illustrating a method 500 that supports memory block maintenance prioritization based on access frequency in accordance with examples as disclosed herein. The operations of method 500 may be implemented by a memory system or its components as described herein. For example, the operations of method 500 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 505, the method may include performing a plurality of access operations to access data stored to a plurality of memory cells within the memory system. In some examples, aspects of the operations of 505 may be performed by an access component 325 as described with reference to FIG. 3.

At 510, the method may include storing, based at least in part on the plurality of access operations, information that indicates, for each LBA of a plurality of LBAs of the memory system, a respective quantity of accesses associated with each LBA within a threshold duration. In some examples, aspects of the operations of 510 may be performed by an access information component 330 as described with reference to FIG. 3.

At 515, the method may include performing, during an idle mode of the memory system, a first refresh of a first memory cell based at least in part on the information indicating that a first LBA of the first memory cell is associated with a first quantity of accesses within the threshold duration that is greater than other quantities of accesses associated with other LBAs of the plurality of LBAs. In some examples, aspects of the operations of 515 may be performed by a refresh component 335 as described with reference to FIG. 3.

At 520, the method may include performing, during the idle mode of the memory system and after the first refresh, a second refresh of a second memory cell based at least in part on the information indicating that a second LBA of the second memory cell is associated with a second quantity of accesses within the threshold duration that is less than the first quantity of accesses. In some examples, aspects of the operations of 520 may be performed by a refresh component 335 as described with reference to FIG. 3.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 16: A method, apparatus, or non-transitory computer-readable medium including operations, features, circuitry, logic, means, or instructions, or any combination thereof for performing a plurality of access operations to access data stored to a plurality of memory cells within the memory system; storing, based at least in part on the plurality of access operations, information that indicates, for each LBA of a plurality of LBAs of the memory system, a respective quantity of accesses associated with each LBA within a threshold duration; performing, during an idle mode of the memory system, a first refresh of a first memory cell based at least in part on the information indicating that a first LBA of the first memory cell is associated with a first quantity of accesses within the threshold duration that is greater than other quantities of accesses associated with other LBAs of the plurality of LBAs; and performing, during the idle mode of the memory system and after the first refresh, a second refresh of a second memory cell based at least in part on the information indicating that a second LBA of the second memory cell is associated with a second quantity of accesses within the threshold duration that is less than the first quantity of accesses.

Aspect 17: The method, apparatus, or non-transitory computer-readable medium of aspect 16, further including operations, features, circuitry, logic, means, or instructions, or any combination thereof for performing a refresh maintenance operation during the idle mode of the memory system, where the refresh maintenance operation includes the first refresh and the second refresh.

Aspect 18: The method, apparatus, or non-transitory computer-readable medium of any of aspects 16 through 17, further including operations, features, circuitry, logic, means, or instructions, or any combination thereof for performing, during the idle mode of the memory system and before the first refresh, a third refresh of a third memory cell based at least in part on a third LBA of the third memory cell having a quantity of errors that is above a threshold quantity of errors.

Aspect 19: The method, apparatus, or non-transitory computer-readable medium of any of aspects 16 through 18, further including operations, features, circuitry, logic, means, or instructions, or any combination thereof for performing, during the idle mode of the memory system and before the first refresh, a third refresh of a third memory cell based at least in part on a third LBA of the third memory cell being associated with one or more wear metrics above a wear metric threshold.

Aspect 20: The method, apparatus, or non-transitory computer-readable medium of aspect 19, where the one or more wear metrics include a duration since a most recent refresh of the third memory cell, a shift in a threshold voltage of the third memory cell, or both.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memories storing processor-executable code; and
one or more processors coupled with the one or more memories and individually or collectively operable to execute the code to cause the memory system to:
perform a plurality of access operations to access data stored to a plurality of memory cells within the memory system;
store, based at least in part on the plurality of access operations, information that indicates, for each logical block address of a plurality of logical block addresses of the memory system, a respective quantity of accesses associated with each logical block address within a threshold duration; and
perform a refresh maintenance operation comprising a plurality of refreshes of the plurality of memory cells within the memory system, wherein the plurality of refreshes are performed in a refresh priority order that is based at least in part on the information.

2. The memory system of claim 1, wherein, to perform the refresh maintenance operation, the one or more processors are individually or collectively operable to execute the code to cause the memory system to:
refresh, in accordance with the refresh priority order, a first memory cell associated with a first logical block address before refreshing a second memory cell associated with a second logical block address based at least in part on the information indicating that the first logical block address is accessed more frequently than the second logical block address within the threshold duration, wherein the refresh priority order prioritizes logical block addresses with greater access frequencies over logical block addresses with lower access frequencies.

3. The memory system of claim 1, wherein, to store the information, the one or more processors are individually or collectively operable to execute the code to cause the memory system to:
store the information within the memory system, wherein the information maps each logical block address of the plurality of logical block addresses to a respective count that indicates the respective quantity of accesses associated with each logical block address within the threshold duration.

4. The memory system of claim 3, wherein the information is stored in non-volatile memory within the memory system for the threshold duration.

5. The memory system of claim 3, wherein the information is stored in volatile memory.

6. The memory system of claim 1, wherein:
the refresh priority order is further based at least in part on a respective range, of a plurality of ranges of wear metrics associated with the memory system, that is associated with each logical block address of the plurality of logical block addresses, and
the plurality of ranges of wear metrics comprises a plurality of ranges of threshold voltage shifts associated with each memory cell of the plurality of memory cells, a plurality of ranges of time periods since a most recent refresh of each memory cell of the plurality of memory cells, or any combination thereof.

7. The memory system of claim 6, wherein, to perform the refresh maintenance operation, the one or more processors are individually or collectively operable to execute the code to cause the memory system to:
perform, in accordance with a first priority in the refresh priority order, one or more first refreshes of a first subset of memory cells that is included within a first range of the plurality of ranges of wear metrics, wherein the first subset of memory cells is associated with the first priority in the refresh priority order based at least in part on the first subset of memory cells being included within the first range having a higher priority than other ranges within the plurality of ranges of wear metrics, and wherein the one or more first refreshes are performed in accordance with a refresh sub-priority order that is based at least in part on the information; and
perform, after performing the one or more first refreshes and in accordance with a second priority in the refresh priority order, one or more second refreshes of a second subset of memory cells that is included within a second range of the plurality of ranges of wear metrics, wherein the second subset of memory cells is associated with the second priority in the refresh priority order based at least in part on the second subset of memory cells being included within the second range having a lower priority than the first range and a higher priority than one or more other ranges of the plurality of ranges of wear metrics, and wherein the one or more second refreshes are performed in accordance with the refresh sub-priority order that is based at least in part on the information.

8. The memory system of claim 6, wherein, to perform the refresh maintenance operation, the one or more processors are individually or collectively operable to execute the code to cause the memory system to:
perform, in accordance with a first priority in the refresh priority order, one or more first refreshes of a first subset of memory cells associated with a first subset of logical block addresses, wherein the first subset of logical block addresses is associated with the first priority based at least in part on the first subset of logical block addresses being included within a threshold set of one or more first ranges, of the plurality of ranges of wear metrics; and
perform, after performing the one or more first refreshes and in accordance with a second priority in the refresh priority order, one or more second refreshes of a second subset of memory cells based at least in part on the information indicating that logical block addresses of the second subset of memory cells are associated with more frequent accesses, within the threshold duration, than one or more other logical block addresses of the plurality of logical block addresses.

9. The memory system of claim 6, wherein, to perform the refresh maintenance operation, the one or more processors are individually or collectively operable to execute the code to cause the memory system to:
perform one or more first refreshes of one or more memory cells associated with a first subset of logical block addresses within a first range of the plurality of ranges of wear metrics; and
move, based at least in part on the one or more first refreshes, the first subset of logical block addresses to a second range of the plurality of ranges of wear metrics, the second range associated with a lower priority in the refresh priority order than the first range.

10. The memory system of claim 6, wherein the plurality of ranges of wear metrics comprises a plurality of block family error avoidance (BFEA) bins.

11. The memory system of claim 1, wherein the one or more processors are individually or collectively further operable to execute the code to cause the memory system to:
detect, in accordance with one or more read operations included in the plurality of access operations, one or more logical block addresses of the memory system that are associated with respective quantities of errors that satisfy a threshold error quantity, wherein the refresh priority order comprises a first priority for performing refreshes on the one or more logical block addresses that are associated with the respective quantities of errors that satisfy the threshold error quantity, and a second priority, lower than the first priority, that is based at least in part on the information.

12. The memory system of claim 1, wherein the one or more processors are individually or collectively further operable to execute the code to cause the memory system to:
receive an indication of the threshold duration, wherein the information is based at least in part on the indication of the threshold duration.

13. The memory system of claim 1, wherein the one or more processors are individually or collectively further operable to execute the code to cause the memory system to:
retain, in the memory system, the information for the plurality of logical block addresses after performing the plurality of refreshes of the plurality of memory cells associated with the plurality of logical block addresses.

14. The memory system of claim 1, wherein the one or more processors are individually or collectively further operable to execute the code to cause the memory system to:
reset, in response to performing the plurality of refreshes of the plurality of memory cells, the information for one or more logical block addresses associated with the plurality of memory cells.

15. The memory system of claim 1, wherein the one or more processors are individually or collectively further operable to execute the code to cause the memory system to:
detect a pattern of access operations performed during a boot-up operation of the memory system, wherein the information is further based at least in part on the pattern of access operations.

16. A memory system, comprising:
one or more memories storing processor-executable code; and
one or more processors coupled with the one or more memories and individually or collectively operable to execute the code to cause the memory system to:
perform a plurality of access operations to access data stored to a plurality of memory cells within the memory system;
store, based at least in part on the plurality of access operations, information that indicates, for each logical block address of a plurality of logical block addresses of the memory system, a respective quantity of accesses associated with each logical block address within a threshold duration;
perform, during an idle mode of the memory system, a first refresh of a first memory cell based at least in part on the information indicating that a first logical block address of the first memory cell is associated with a first quantity of accesses within the threshold duration that is greater than other quantities of accesses associated with other logical block addresses of the plurality of logical block addresses; and
perform, during the idle mode of the memory system and after the first refresh, a second refresh of a second memory cell based at least in part on the information indicating that a second logical block address of the second memory cell is associated with a second quantity of accesses within the threshold duration that is less than the first quantity of accesses.

17. The memory system of claim 16, wherein the one or more processors are individually or collectively further operable to execute the code to cause the memory system to:
perform a refresh maintenance operation during the idle mode of the memory system, wherein the refresh maintenance operation comprises the first refresh and the second refresh.

18. The memory system of claim 16, wherein the one or more processors are individually or collectively further operable to execute the code to cause the memory system to:
perform, during the idle mode of the memory system and before the first refresh, a third refresh of a third memory cell based at least in part on a third logical block address of the third memory cell having a quantity of errors that is above a threshold quantity of errors.

19. The memory system of claim 16, wherein the one or more processors are individually or collectively further operable to execute the code to cause the memory system to:
perform, during the idle mode of the memory system and before the first refresh, a third refresh of a third memory cell based at least in part on a third logical block address of the third memory cell being associated with one or more wear metrics above a wear metric threshold.

20. The memory system of claim 19, wherein the one or more wear metrics comprise a duration since a most recent refresh of the third memory cell, a shift in a threshold voltage of the third memory cell, or both.

21. A method by a memory system, comprising:
performing a plurality of access operations to access data stored to a plurality of memory cells within the memory system;
storing, based at least in part on the plurality of access operations, information that indicates, for each logical block address of a plurality of logical block addresses of the memory system, a respective quantity of accesses associated with each logical block address within a threshold duration; and
performing a refresh maintenance operation comprising a plurality of refreshes of the plurality of memory cells within the memory system, wherein the plurality of refreshes are performed in a refresh priority order that is based at least in part on the information.

22. The method of claim 21, wherein performing the refresh maintenance operation comprises:
refreshing, in accordance with the refresh priority order, a first memory cell associated with a first logical block address before refreshing a second memory cell associated with a second logical block address based at least in part on the information indicating that the first logical block address is accessed more frequently than the second logical block address within the threshold duration, wherein the refresh priority order prioritizes logical block addresses with greater access frequencies over logical block addresses with lower access frequencies.

23. The method of claim 21, wherein storing the information comprises:
storing the information within the memory system, wherein the information maps each logical block address of the plurality of logical block addresses to a respective count that indicates the respective quantity of accesses associated with each logical block address within the threshold duration.

24. A method by a memory system, comprising:
performing a plurality of access operations to access data stored to a plurality of memory cells within the memory system;
storing, based at least in part on the plurality of access operations, information that indicates, for each logical block address of a plurality of logical block addresses of the memory system, a respective quantity of accesses associated with each logical block address within a threshold duration;
performing, during an idle mode of the memory system, a first refresh of a first memory cell based at least in part on the information indicating that a first logical block address of the first memory cell is associated with a first quantity of accesses within the threshold duration that is greater than other quantities of accesses associated with other logical block addresses of the plurality of logical block addresses; and
performing, during the idle mode of the memory system and after the first refresh, a second refresh of a second memory cell based at least in part on the information indicating that a second logical block address of the second memory cell is associated with a second quantity of accesses within the threshold duration that is less than the first quantity of accesses.

25. The method of claim 24, further comprising:
performing a refresh maintenance operation during the idle mode of the memory system, wherein the refresh maintenance operation comprises the first refresh and the second refresh.

26. The method of claim 24, further comprising:
performing, during the idle mode of the memory system and before the first refresh, a third refresh of a third memory cell based at least in part on a third logical block address of the third memory cell having a quantity of errors that is above a threshold quantity of errors.

27. The method of claim 24, further comprising:
performing, during the idle mode of the memory system and before the first refresh, a third refresh of a third memory cell based at least in part on a third logical block address of the third memory cell being associated with one or more wear metrics above a wear metric threshold.

28. A non-transitory computer-readable medium storing code comprising instructions which, when executed by one or more processors of a memory system, cause the memory system to:
perform a plurality of access operations to access data stored to a plurality of memory cells within the memory system;
store, based at least in part on the plurality of access operations, information that indicates, for each logical block address of a plurality of logical block addresses of the memory system, a respective quantity of accesses associated with each logical block address within a threshold duration; and
perform a refresh maintenance operation comprising a plurality of refreshes of the plurality of memory cells within the memory system, wherein the plurality of refreshes are performed in a refresh priority order that is based at least in part on the information.

29. The non-transitory computer-readable medium of claim 28, wherein the instructions to perform the refresh maintenance operation, when executed by the one or more processors of the memory system, cause the memory system to:
refresh, in accordance with the refresh priority order, a first memory cell associated with a first logical block address before refreshing a second memory cell associated with a second logical block address based at least in part on the information indicating that the first logical block address is accessed more frequently than the second logical block address within the threshold duration, wherein the refresh priority order prioritizes logical block addresses with greater access frequencies over logical block addresses with lower access frequencies.

30. The non-transitory computer-readable medium of claim 28, wherein the instructions to store the information, when executed by the one or more processors of the memory system, cause the memory system to:
store the information within the memory system, wherein the information maps each logical block address of the plurality of logical block addresses to a respective count that indicates the respective quantity of accesses associated with each logical block address within the threshold duration.
